(19) United States
(12) Patent Application Publication
(10) Pub. No.: US 2024/0093370 A1
(43) Pub. Date: Mar. 21, 2024

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: KOKUSAI ELECTRIC CORPORATION, Tokyo (JP)

(72) Inventors: Masahiro TAKAHASHI, Toyama (JP); Hideki HORITA, Toyama (JP); Atsushi MORIYA, Toyama (JP)

(73) Assignee: KOKUSAI ELECTRIC CORPORATION, Tokyo (JP)

(21) Appl. No.: 18/226,854

(22) Filed: Jul. 27, 2023

(30) Foreign Application Priority Data
Sep. 16, 2022 (JP) 2022-147959

(51) Int. Cl. C23C 16/52; C23C 16/44; H01L 21/02; H01L 21/67

(52) U.S. Cl. CPC C23C 16/52; C23C 16/4408; C23C 16/4412; H01L 21/0228; H01L 21/67017

(57) ABSTRACT

According to one aspect of the present disclosure, there is provided a substrate processing method including: forming a film containing a predetermined element on a substrate by performing a first cycle a first predetermined number of times, the first cycle including: forming a first layer containing the predetermined element by performing a second cycle a second predetermined number of times, wherein a surface of the first layer is halogen-terminated and wherein the second cycle includes: supplying a first gas containing the predetermined element and a halogen element to the substrate; and removing the first gas; and forming a second layer containing the predetermined element by supplying a second gas containing the predetermined element to the substrate.

### CROSS-REFERENCE TO RELATED PATENT APPLICATION

This non-provisional U.S. patent application is based on and claims priority under 35 U.S.C. § 119 of Japanese Patent Application No. 2022-147959, filed on Sep. 16, 2022, in the Japanese Patent Office, the entire contents of which are hereby incorporated by reference.

### BACKGROUND

### 1. Field

The present disclosure relates to a substrate processing method, a method of manufacturing a semiconductor device, a non-transitory computer-readable recording medium and a substrate processing apparatus.

### 2. Related Art

According to some related arts, as a part of a manufacturing process of a semiconductor device, a film-forming process of forming a film may be performed by repeatedly performing a film-forming step and an etching step.

However, in the film-forming process according to the related arts, for example, it may be difficult to form a film with a desired thickness distribution in a concave structure (recess) with respect to a substrate provided with the concave structure formed on a surface thereof.

### SUMMARY

According to the present disclosure, there is provided a technique capable of forming a film with a desired thickness distribution, for example, in a concave structure of a substrate.

According to an aspect the technique of the present disclosure, there is provided a substrate processing method including: (A) forming a film containing a predetermined element on a substrate by performing a first cycle a first predetermined number of times, wherein the first cycle includes: (a) forming a first layer containing the predetermined element by performing a second cycle a second predetermined number of times, wherein a surface of the first layer is halogen-terminated and wherein the second cycle includes: (a1) supplying a first gas containing the predetermined element and a halogen element to the substrate; and (a2) removing the first gas from a space in which the substrate is accommodated; and (b) forming a second layer containing the predetermined element by supplying a second gas containing the predetermined element to the substrate on which the first layer is formed.

### BRIEF DESCRIPTION OF THE DRAWINGS

FIG. 1 is a diagram schematically illustrating a vertical cross-section of a vertical type process furnace 202 of a substrate processing apparatus preferably used in one or more embodiments of the present disclosure.

FIG. 2 is a diagram schematically illustrating a horizontal cross-section, taken along a line A-A shown in FIG. 1, of the vertical type process furnace 202 of the substrate processing apparatus preferably used in the embodiments of the present disclosure.

FIG. 3 is a block diagram schematically illustrating a configuration of a controller 121 and related components of the substrate processing apparatus preferably used in the embodiments of the present disclosure.

FIG. 4 is a diagram schematically illustrating a process sequence according to the embodiments of the present disclosure.

FIG. 5A is a diagram schematically illustrating a partially enlarged cross-section of a surface of a wafer 200 provided with a concave structure 300.

FIG. 5B is a diagram schematically illustrating a partially enlarged cross-section of the surface of the wafer 200 after forming a first layer in the concave structure 300.

FIG. 5C is a diagram schematically illustrating a partially enlarged cross-section of the surface of the wafer 200 after forming a second layer in the concave structure 300.

FIG. 5D is a diagram schematically illustrating a partially enlarged cross-section of the surface of the wafer 200 after an entirety of the concave structure 300 is filled with a film 308.

### DETAILED DESCRIPTION

### Embodiments of Present Disclosure

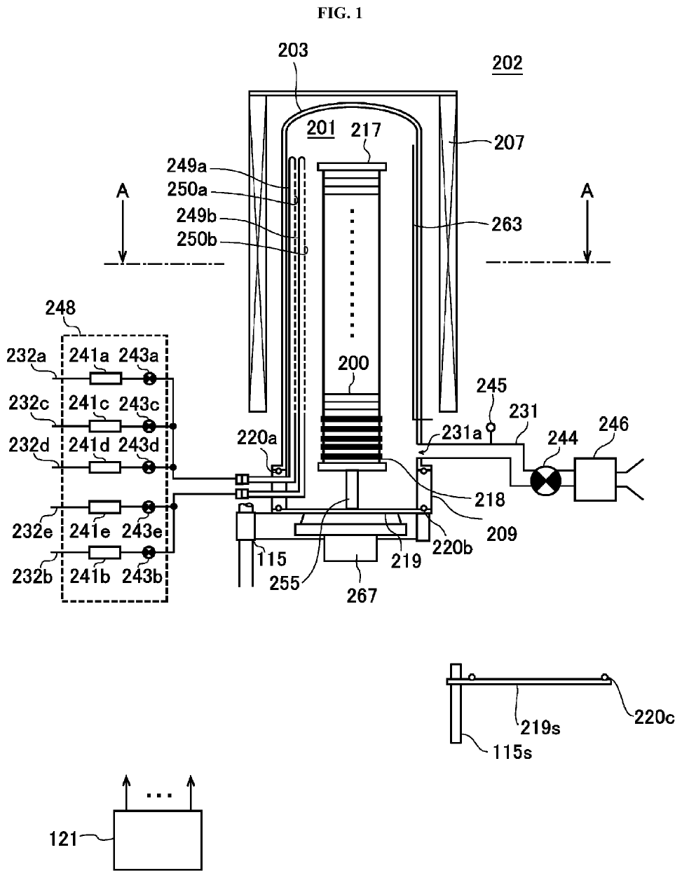

Hereinafter, one or more embodiments (also simply referred to as “embodiments”) of the technique of the present disclosure will be described in detail mainly with reference to FIGS. 1 through 4 and FIGS. 5A through 5D. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

(1) Configuration of Substrate Processing Apparatus

As shown in FIG. 1, a substrate processing apparatus according to the present embodiments includes a vertical type process furnace (also simply referred to as a “process furnace”) 202. The process furnace 202 includes a heater 207 serving as a temperature regulator (which is a temperature adjusting structure, a heating structure or a heating system). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers including a wafer 200 serving as a substrate. Hereinafter, the plurality of wafers including the wafer 200 may also be simply referred to as “wafers 200”. The wafer 200 is processed in the process chamber 201.

Nozzles 249a and 249b are provided in the process chamber 201 so as to penetrate a side wall of the manifold 209. The nozzle 249a serves as a first supplier (which is a first supply structure) and the nozzle 249b serves as a second supplier (which is a second supply structure). The nozzle 249a may also be referred to as a “first nozzle 249a”, and the nozzle 249b may also be referred to as a “second nozzle 249b”. For example, each of the nozzles 249a and 249b may be made of a heat resistant material such as quartz and silicon carbide (SiC). Gas supply pipes 232a and 232b are connected to the nozzles 249a and 249b, respectively. The nozzles 249a and 249b are different nozzles. The nozzles 249a and 249b are provided adjacent to each other.

Mass flow controllers (also simply referred to as “MFCs”) 241a and 241b serving as flow rate controllers (flow rate control structures) and valves 243a and 243b serving as opening/closing valves are sequentially installed at the gas supply pipes 232a and 232b, respectively, in this order from upstream sides to downstream sides of the gas supply pipes 232a and 232b in a gas flow direction. Gas supply pipes 232c and 232d are connected to the gas supply pipe 232a at a downstream side of the valve 243a of the gas supply pipe 232a. A gas supply pipe 232e is connected to the gas supply pipe 232b at a downstream side of the valve 243b of the gas supply pipe 232b. MFCs 241c, 241d and 241e and valves 243c, 243d and 243e are sequentially installed at the gas supply pipes 232c, 232d and 232e, respectively, in this order from upstream sides to downstream sides of the gas supply pipes 232c, 232d and 232e in the gas flow direction. For example, each of the gas supply pipes 232a through 232e is made of a metal material such as SUS.

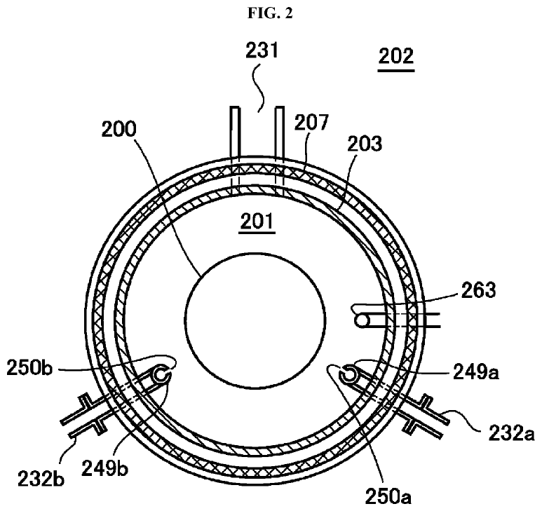

As shown in FIGS. 1 and 2, each of the nozzles 249a and 249b is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a wafer arrangement direction). That is, each of the nozzles 249a and 249b is installed in a region that is located beside and horizontally surrounds a wafer arrangement region in which the wafers 200 are arranged (stacked) along the wafer arrangement direction. A plurality of gas supply holes 250a and a plurality of gas supply holes 250b are provided at side surfaces of the nozzles 249a and 249b, respectively. The gas supply holes 250a and the gas supply holes 250b are open toward a center of the wafer 200 when viewed from above, and are configured such that gases are capable of being supplied toward the wafers 200 via the gas supply holes 250a and the gas supply holes 250b. The gas supply holes 250a and the gas supply holes 250b are provided from the lower portion toward the upper portion of the reaction tube 203.

A first gas containing a predetermined element and a halogen element is supplied into the process chamber 201 through the gas supply pipe 232a provided with the MFC 241a and the valve 243a and the nozzle 249a.

A second gas containing the predetermined element contained in the first gas is supplied into the process chamber 201 through the gas supply pipe 232b provided with the MFC 241b and the valve 243b and the nozzle 249b.

An etching gas is supplied into the process chamber 201 through the gas supply pipe 232c provided with the MFC 241c and the valve 243c and the nozzle 249a.

An inert gas is supplied into the process chamber 201 through the gas supply pipes 232d and 232e provided with the MFCs 241d and 241e and the valves 243d and 243e, respectively, the gas supply pipes 232a and 232b and the nozzles 249a and 249b. The inert gas acts as a purge gas, a carrier gas, a dilution gas and the like.

A first gas supplier (which is a first gas supply structure or a first gas supply system) is constituted mainly by the gas supply pipe 232a, the MFC 241a and the valve 243a. A second gas supplier (which is a second gas supply structure or a second gas supply system) is constituted mainly by the gas supply pipe 232b, the MFC 241b and the valve 243b. An etching gas supplier (which is an etching gas supply structure or an etching gas supply system) is constituted mainly by the gas supply pipe 232c, the MFC 241c and the valve 243c. Further, an inert gas supplier (which is an inert gas supply structure or an inert gas supply system) is constituted mainly by the gas supply pipes 232d and 232e, the MFCs 241d and 241e and the valves 243d and 243e.

Since the second gas acts as a source gas (film-forming gas), the second gas supplier may also be referred to as a source gas supplier (which is a source gas supply structure or a source gas supply system), or may also be referred to as a film-forming gas supplier (which is a film-forming gas supply structure or a film-forming gas supply system). Further, since the first gas acts as a film-forming inhibitory gas, the first gas supplier may also be referred to as a film-forming inhibitory gas supplier (which is a film-forming inhibitory gas supply structure or a film-forming inhibitory gas supply system).

Any one or an entirety of the gas suppliers described above may be embodied as an integrated gas supply system 248 in which the components such as the valves 243a through 243e and the MFCs 241a through 241e are integrated. The integrated gas supply system 248 is connected to the respective gas supply pipes 232a through 232e. An operation of the integrated gas supply system 248 to supply various substances (various gases) to the gas supply pipes 232a through 232e, for example, operations such as an operation of opening and closing the valves 243a through 243e and an operation of adjusting flow rates of the gases through the MFCs 241a through 241e may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a through 232e on a basis of the integrated structure. Operations such as maintenance, replacement and addition for the integrated gas supply system 248 may be performed on a basis of the integrated structure.

An exhaust port 231a through which an inner atmosphere of the process chamber 201 is exhausted is provided at a lower side wall of the reaction tube 203. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to perform a vacuum exhaust operation of the process chamber 201 or stop the vacuum exhaust operation. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (or closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. A rotating shaft 255 of the rotator 267 is connected to the boat 217 through the seal cap 219. For example, the rotating shaft 255 of the rotator 267 is made of a metal material such as SUS. As the rotator 267 rotates the boat 217, the wafers 200 accommodated in the boat 217 are rotated. The seal cap 219 is elevated or lowered in the vertical direction by a boat elevator 115 serving as an elevating structure provided outside the reaction tube 203. The boat elevator 115 serves as a transfer device (which is a transfer structure or a transfer system) capable of transferring (loading) the wafers 200 into the process chamber 201 and capable of transferring (unloading) the wafers 200 out of the process chamber 201 by elevating and lowering the seal cap 219. The transfer device functions as a providing device capable of providing the wafer 200 into the process chamber 201.

A shutter 219s serving as a furnace opening lid capable of airtightly sealing (or closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 (which is a substrate support or a substrate retainer) is configured such that the wafers 200 (for example, 25 wafers to 200 wafers) are accommodated (or supported) in the vertical direction in the boat 217 while the wafers 200 are horizontally oriented with their centers aligned with one another with a predetermined interval therebetween in a multistage manner. That is, the wafers 200 are arranged in a direction perpendicular to a surface of the wafer 200. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

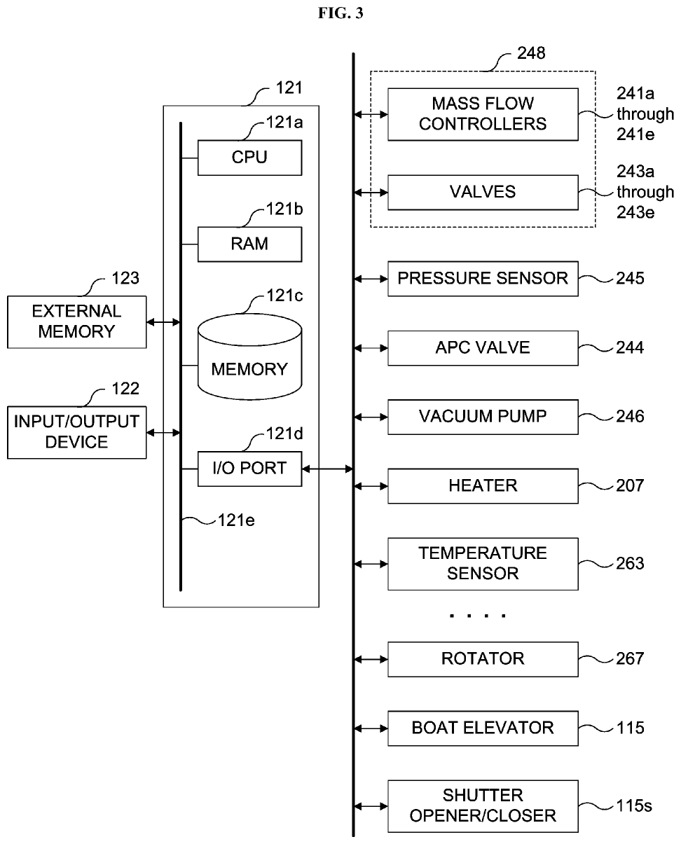

As shown in FIG. 3, the controller 121 serving as a control device (control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus 121e. For example, an input/output device 122 constituted by a component such as a touch panel is connected to the controller 121. Further, the controller 121 is configured such that an external memory 123 can be connected to the controller 121.

The memory 121c is configured by a component such as a flash memory, a hard disk drive (HDD) and a solid state drive (SSD). For example, a control program configured to control an operation of the substrate processing apparatus and a process recipe containing information on sequences and conditions of a substrate processing described later may be readably stored in the memory 121c. The process recipe is obtained by combining steps (sequences or processes) of the substrate processing described later such that the controller 121 can execute the steps to acquire a predetermined result, and functions as a program. Hereinafter, the process recipe and the control program may be collectively or individually referred to as a “program”. In addition, the process recipe may also be simply referred to as a “recipe”. Thus, in the present specification, the term “program” may refer to the recipe alone, may refer to the control program alone or may refer to both of the recipe and the control program. The RAM 121b functions as a memory area (work area) where a program or data read by the CPU 121a is temporarily stored.

The I/O port 121d is connected to the components described above such as the MFCs 241a through 241e, the valves 243a through 243e, the pressure sensor 245, the APC valve 244, the vacuum pump 246, the temperature sensor 263, the heater 207, the rotator 267, the boat elevator 115 and the shutter opener/closer 115s.

The CPU 121a is configured to read the control program from the memory 121c and execute the read control program. In addition, the CPU 121a is configured to read the recipe from the memory 121c, for example, in accordance with an operation command inputted from the input/output device 122. In accordance with the contents of the read recipe, the CPU 121a may be configured to be capable of controlling various operations such as flow rate adjusting operations for various substances (various gases) by the MFCs 241a through 241e, opening and closing operations of the valves 243a through 243e, an opening and closing operation of the APC valve 244, a pressure regulating operation (pressure adjusting operation) by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program written and stored in the external memory 123 into the computer. For example, the external memory 123 may include a magnetic disk such as a hard disk drive (HDD), an optical disk such as a CD, a magneto-optical disk such as an MO and a semiconductor memory such as a USB memory and a solid state drive (SSD). The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone or may refer to both of the memory 121c and the external memory 123. Instead of the external memory 123, a communication interface such as the Internet and a dedicated line may be used for providing the program to the computer.

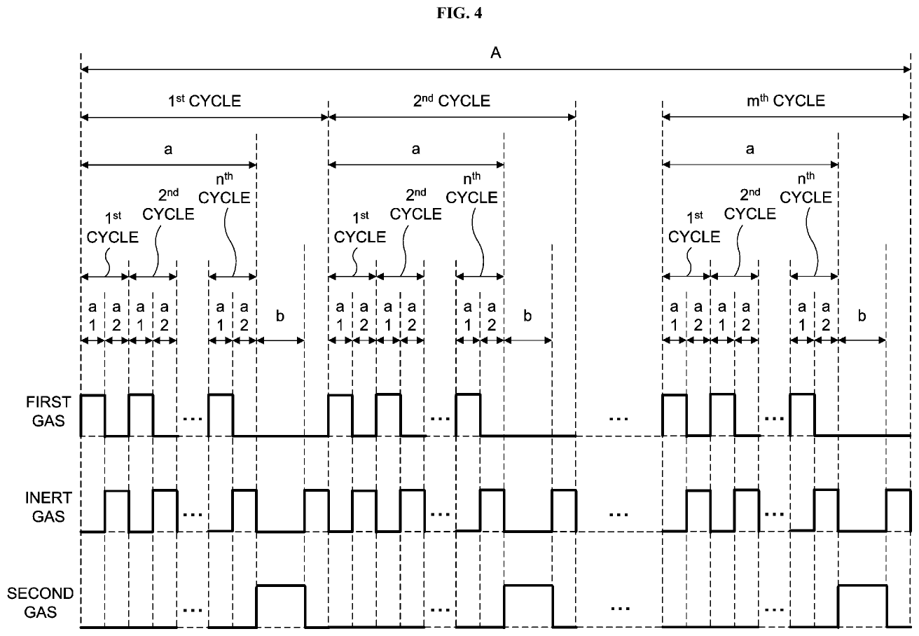

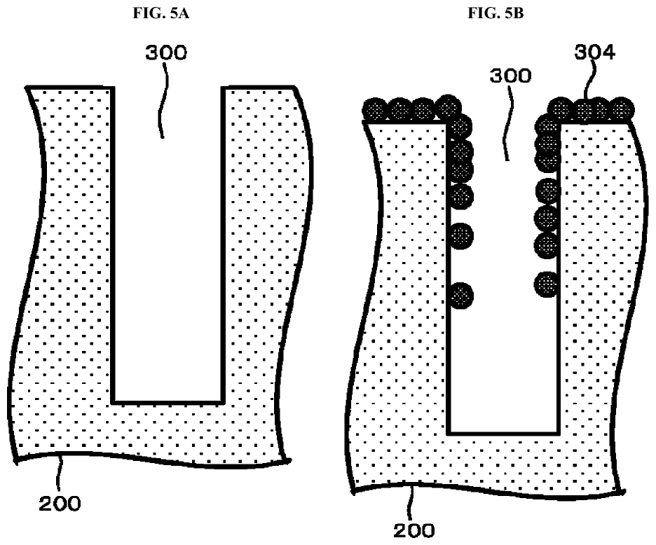

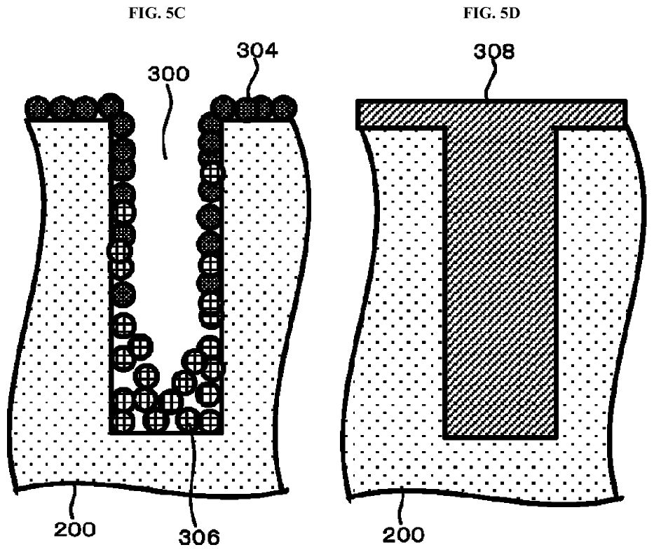

(2) Substrate Processing Hereinafter, an exemplary flow (exemplary process sequence) of the substrate processing such as a film-forming process of forming a film on the wafer 200 serving as the substrate will be described mainly with reference to FIGS. 4, 5A through 5D. The substrate processing serves as a part of a manufacturing process of a semiconductor device, and is performed by using the substrate processing apparatus described above. The present embodiments will be described by way of an example in which a concave structure (recess) 300 is provided on the surface of the wafer 200. In the present specification, the term “concave structure” may refer to not only a trench or a hole, but also a structure provided with a large internal surface area relative to an opening thereof, such as a lateral hole and a through-hole. In the following descriptions, the operations of components constituting the substrate processing apparatus are controlled by the controller 121.

The exemplary process sequence of the substrate processing according to the present embodiments may include: a step (A) of forming a film 308 containing the predetermined element on the wafer 200 in the process chamber 201 by performing a first cycle a first predetermined number of times (m times, where m is an integer equal to or greater than 1). The first cycle may include: a step (a) of forming a first layer 304 containing the predetermined element on the wafer 200 in the process chamber 201 by performing a second cycle a second predetermined number of times (n times, where n is an integer equal to or greater than 1), wherein a surface of the first layer 304 is halogen-terminated; and a step (b) of forming a second layer 306 containing the predetermined element on the wafer 200 by supplying the second gas containing the predetermined element to the wafer 200 on which the first layer 304 is formed. The second cycle may include: a step (a1) of supplying the first gas containing the predetermined element and the halogen element to the wafer 200 in the process chamber 201; and a step (a2) of removing the first gas from the process chamber 201. Further, reference numerals “A”, “a”, “a1”, “a2” and “b” shown in FIG. 4 indicate the steps (A), (a), (a1), (a2) and (b) of the exemplary process sequence of the substrate processing, respectively.

Hereinafter, an example in which a silicon (Si) film is formed as the film 308 will be described.

In the present specification, the process sequence described above may be illustrated as follows. Process sequences of modified examples and other embodiments, which will be described later, will be also represented in the same manner.

[(first gas→purge)×n→second gas]×m

Further, as in a process sequence shown in FIG. 4 and described below, a purge step may be performed after supplying the second gas. The present embodiments will be described by way of an example in which the purge step is performed after supplying the second gas.

[(first gas→purge)×n→second gas→purge]×m

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

<Wafer Charging Step and Boat Loading Step>

The wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 supporting the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

As the wafer 200, for example, a single crystal silicon (Si) wafer may be used. In addition, the concave structure 300 is provided on the surface of the wafer 200, as shown in FIGS. 5A through 5D. A material constituting a surface (outermost surface) in the concave structure 300, that is, a surface of an inner wall of the concave structure 300 is not particularly limited. For example, as the material constituting the surface in the concave structure 300, a substance such as single crystal silicon (that is, a single crystal silicon wafer itself), a silicon film (Si film), a germanium film (Ge film), a silicon germanium film (SiGe film), a silicon carbide film (SiC film), a silicon nitride film (SiN film), a silicon carbonitride film (SiCN film), a silicon oxide film (SiO film), a silicon oxynitride film (SiON), a silicon oxycarbide film (SiOC film), a silicon oxycarbonitride film (SiOCN film), a silicon boronitride film (SiBN film), a silicon borocarbonitride film (SiBCN film) and a boronitride film (BN film) may be used. For example, one or more exemplified as the substance may be used as the material constituting the surface in the concave structure 300.

<Pressure Adjusting Step and Temperature Adjusting Step>

After the boat loading step is completed, the vacuum pump 246 vacuum-exhausts (decompresses and exhausts) the inner atmosphere of the process chamber 201 (that is, a space in which the wafers 200 are accommodated) such that the inner pressure of the process chamber 201 reaches and is maintained at a desired pressure (vacuum degree) (pressure adjusting step). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245. In addition, the heater 207 heats the process chamber 201 such that a temperature of the wafer 200 in the process chamber 201 reaches and is maintained at a desired film-forming temperature (temperature adjusting step). When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained. In addition, a rotation of the wafer 200 is started by the rotator 267. The vacuum pump 246 continuously vacuum-exhausts the inner atmosphere of the process chamber 201, the heater 207 continuously heats the wafer 200 in the process chamber 201 and the rotator 267 continuously rotates the wafer 200 until at least a processing of the wafer 200 is completed.

Thereafter, the step (A) is performed, that is, the step (a) including the steps (a1) and (a2) and the step (b) are performed so as to perform the film-forming process of forming the film 308 on the wafer 200. In the present specification, the film-forming process of forming the film 308 in the concave structure 300 provided on the surface of the wafer 200 may also be referred to as a “filling process”. Hereinafter, the steps mentioned above will be described in detail.

<Step (a1)>

In the step (a1), the first gas is supplied to the wafer 200 in the process chamber 201.

Specifically, the valve 243a is opened such that the first gas is supplied into the gas supply pipe 232a. A flow rate of the first gas supplied into the gas supply pipe 232a is adjusted by the MFC 241a. Then, the first gas whose flow rate is adjusted is supplied into the process chamber 201 through the nozzle 249a, and is exhausted through the exhaust port 231a. Thereby, the first gas is supplied to the wafer 200. Thus, the step (a1) may also be referred to as a “first gas supply step”. In the present step, simultaneously with a supply of the first gas, the valves 243d and 243e may be opened such that the inert gas is supplied into the process chamber 201 through each of the nozzles 249a and 249b.

For example, the process conditions of the present step are as follows:
A process temperature: from 300° C. to 600° C., preferably from 400° C. to 500° C.;
A process pressure: from 1 kPa to 100 kPa, preferably from 20 kPa to 50 kPa;
A supply flow rate of the first gas: from 0.1 slm to 1 slm, preferably from 0.2 slm to 0.5 slm;
A supply time (time duration) of the first gas: from 1 minute to 10 minutes, preferably from 3 minutes to 6 minutes; and
A supply flow rate of the inert gas (for each gas supply pipe): from 0 slm to 0.5 slm.

In the present specification, a notation of a numerical range such as “from 300° C. to 600° C.” means that a lower limit and an upper limit are included in the numerical range. Therefore, for example, a numerical range “from 300° C. to 600° C.” means a range equal to or higher than 300° C. and equal to or less than to 600° C. The same also applies to other numerical ranges described in the present specification. Further, in the present specification, the process temperature refers to the temperature of the wafer 200 or the inner temperature of the process chamber 201, and the process pressure refers to the inner pressure of the process chamber 201. Further, when a supply flow rate of a gas is zero (0) slm, it refers to a case where the gas is not supplied. The same also applies to the following descriptions.

By supplying the first gas (for example, a chlorosilane-based gas containing silicon as the predetermined element and chlorine (Cl) as the halogen element and containing a silicon-chlorine bond (Si—Cl bond)) to the wafer 200 in accordance with the process conditions described above, part of Si—Cl bonds contained in molecules of the first gas (that is, the chlorosilane-based gas) can react with the surface of the wafer 200, and the gas can be adsorbed on the surface of the wafer 200. Thereby, it is possible to adsorb the first gas on the surface of the wafer 200. In addition, under the process conditions described above, the remaining Si—Cl bonds that are contained in the molecules of the first gas adsorbed to the surface of the wafer 200 and do not react with the surface of the wafer 200 may remain as they are. Thereby, it is possible to form a chlorine termination (Cl termination) (that is, a silicon-chlorine termination (Si—Cl termination)) serving as a halogen termination on the surface of the wafer 200. An adsorption of the first gas to the surface of the wafer 200 may include not only a case in which the first gas is chemically adsorbed by a reaction of silicon containing a dangling bond with the surface of the wafer 200 but also a case in which the first gas containing the Si—Cl bond is physically adsorbed on the surface of the wafer 200.

After the first gas is adsorbed on the surface of the wafer 200, the valve 243a is closed to stop the supply of the first gas into the process chamber 201.

As the first gas, for example, a halosilane-based gas containing silicon as the predetermined element and the halogen element may be used. As the halogen element, for example, an element such as chlorine (Cl), fluorine (F), bromine (Br) and iodine (I) may be used. As the halosilane-based gas, for example, as described above, the chlorosilane-based gas containing silicon and chlorine may be used.

As the first gas, for example, the chlorosilane-based gas such as dichlorosilane (SiH₂Cl₂, abbreviated as DCS) gas, tetrachlorosilane (SiCl₄, abbreviated as STC) gas, hexachlorodisilane (Si₂Cl₆, abbreviated as HCDS) gas and octachlorotrisilane (Si₃Cl₈, abbreviated as OCTS) gas may be used. As the first gas, for example, one or more of the gases exemplified above as the chlorosilane-based gas may be used.

As the first gas, for example, instead of or in addition to the chlorosilane-based gas, a fluorosilane-based gas such as tetrafluorosilane (SiF₄) gas, difluorosilane (SiH₂F₂) gas, hexafluorodisilane (Si₂F₆, abbreviated as HFDS) gas and octafluorotrisilane (Si₃F₈) gas, a bromosilane-based gas such as tetrabromosilane (SiBr₄) gas, hexabromodisilane (Si₂Br₆, abbreviated as HBDS) gas and octabromotrisilane (Si₃Br₈) gas, and an iodosilane-based gas such as tetraiodosilane (SiI₄, abbreviated as STI) gas, diiodosilane (SiH₂I₂) gas, hexaiododisilane (Si₂I₆, abbreviated as HIDS) gas and octaiodotrisilane (Si₃I₈) gas may be used. As the first gas, for example, one or more of the gases exemplified above as the fluorosilane-based gas, the bromosilane-based gas and the iodosilane-based gas may be used.

As the inert gas, for example, nitrogen (N₂) gas or a rare gas such as argon (Ar) gas, helium (He) gas, neon (Ne) gas and xenon (Xe) gas may be used. As the inert gas, for example, one or more of the gases exemplified above as the inert may be used. The same also applies to the steps described below.

<Step (a2)>

In the step (a2), the inner atmosphere of the process chamber 201 is vacuum-exhausted such that a gas phase substance remaining in the process chamber 201 is removed from the process chamber 201. In the present step, the inert gas is supplied into the process chamber 201.

Specifically, the valves 243d and 243e are opened such that the inert gas is supplied into the gas supply pipes 232a and 232b. A flow rate of the inert gas supplied into the gas supply pipes 232a and 232b is adjusted by each of the MFCs 241d and 241e. Then, the inert gas whose flow rate is adjusted is supplied into the process chamber 201 through the nozzles 249a and 249b, and is exhausted through the exhaust port 231a. In the present step, simultaneously with a supply of the first gas, the valves 243d and 243e may be opened such that the inert gas is supplied into the process chamber 201 through each of the nozzles 249a and 249b. The inert gas supplied through the nozzles 249a and 249b acts as the purge gas, and thereby, the inner atmosphere of the process chamber 201 is purged (purge step).

For example, the process conditions of the present step are as follows:
A process pressure: from 10 Pa to 100 Pa;
A supply flow rate of the inert gas (for each gas supply pipe): from 0.1 slm to 1 slm; and
A supply time (time duration) of the inert gas: from 1 second to 120 seconds, preferably from 1 second to 60 seconds.

The other process conditions of the present step are set to be substantially the same as those of the step (a1).

<Step (a): Performing Second Cycle Second Predetermined Number of Times>

In the step (a), by performing the second cycle wherein the step (a1) and the step (a2) described above are performed non-simultaneously (that is, in a non-synchronized manner) in this order the second predetermined number of times (n times, wherein n is an integer equal to or greater than 1), it is possible to form the first layer 304 on an outermost surface of the wafer 200 serving as a base. For example, a layer containing the predetermined element (for example, silicon) and whose surface is halogen-terminated (chlorine-terminated) is formed as the first layer 304. Further, in FIG. 4,“1St CYCLE”, “2^{nd} CYCLE” and “n^{th} CYCLE” related to the step (a1) and the step (a2) indicate “a first execution of the second cycle”, “a second execution of the second cycle” and “an n^{th} execution of the second cycle”, respectively.

In the present step, for example, it is possible to set a density of the first layer 304 to be higher in a portion of an inner surface of the concave structure 300 than in the other portion of the inner surface of the concave structure 300. Specifically, for example, by reducing the supply flow rate of the first gas per cycle (that is, the second cycle) or by shortening the supply time of the first gas per cycle (that is, the second cycle), it is possible to prevent (or suppress) the first gas from reaching the vicinity of a bottom of the inner surface of the concave structure 300 such that the supply of the first gas is limited to the vicinity of an opening of the inner surface of the concave structure 300. Thereby, for example, it is possible to easily set (adjust) the density of the first layer 304 in the vicinity of the opening of the inner surface of the concave structure 300 to be higher than the density of the first layer 304 in the vicinity of the bottom of the inner surface of the concave structure 300 (see FIG. 5B). In the present step, by setting the second predetermined number of times twice or more, that is, by performing the second cycle described above twice or more, it is possible to more easily set (adjust) the density of the first layer 304. In the present specification, for example, the “density” of the first layer 304 on the inner surface of the concave structure 300 may be considered synonymous with the number of silicon (Si) or the like (which is adsorbed in a manner described above) to which chlorine (CI) or the like is bonded (that is, silicon terminated with chlorine or the like) per unit area on the inner surface of the concave structure 300, or may be considered synonymous with an average thickness of the first layer 304 per unit area on the inner surface of the concave structure 300.

Further, in the present step, by adjusting an execution time of the step (a1) (that is, the supply time of the first gas) per cycle (that is, the second cycle) or by adjusting the supply flow rate of the first gas per cycle (that is, the second cycle), it is possible to adjust a ratio of the density of the first layer 304 formed in the vicinity of the bottom of the inner surface of the concave structure 300 to the density of the first layer 304 formed in the vicinity of the opening of the inner surface of the concave structure 300 to a desired ratio. Specifically, for example, by adjusting the execution time of the step (a1) per cycle (the second cycle) in a direction of shortening from a predetermined time or by adjusting the supply flow rate of the first gas per cycle (the second cycle) in a direction of reducing from a predetermined flow rate, it is possible to control (adjust) the ratio of the density of the first layer 304 formed in the vicinity of the bottom of the inner surface of the concave structure 300 to the density of the first layer 304 formed in the vicinity of the opening of the inner surface of the concave structure 300 to be small.

<Step (b)>

In the step (b), the second gas is supplied to the wafer 200 in the process chamber 201.

Specifically, the valve 243b is opened such that the second gas is supplied into the gas supply pipe 232b. A flow rate of the second gas supplied into the gas supply pipe 232b is adjusted by the MFC 241b. Then, the second gas whose flow rate is adjusted is supplied into the process chamber 201 through the nozzle 249b, and is exhausted through the exhaust port 231a. Thereby, the second gas is supplied to the wafer 200. Thus, the step (b) may also be referred to as a “second gas supply step”. In the present step, simultaneously with a supply of the second gas, the valves 243d and 243e may be opened such that the inert gas is supplied into the process chamber 201 through each of the nozzles 249a and 249b.

For example, the process conditions of the present step are as follows:
A process temperature: from 400° C. to 600° C., preferably from 450° C. to 550° C.;
A process pressure: from 10 Pa to 500 Pa, preferably from 50 Pa to 100 Pa;
A supply flow rate of the second gas: from 1 slm to 5 slm, preferably from 2 slm to 4 slm; and
A supply time (time duration) of the second gas: from 10 minutes to 120 minutes, preferably from 30 minutes to 90 minutes.

The other process conditions of the present step are set to be substantially the same as those of the step (a1).

By supplying the second gas (for example, a silane-based gas containing silicon as the predetermined element) to the wafer 200 in accordance with the process conditions described above, it is possible to form a silicon-containing layer serving as the second layer 306 is formed on the wafer 200. Specifically, for example, it is possible to form the second layer 306 such that a density of the second layer 306 in the vicinity of the opening of the inner surface of the concave structure 300 is lower than the density of the second layer 306 in the vicinity of the bottom of the inner surface of the concave structure 300 (see FIG. 5C). The second layer 306 is formed with such a density distribution because the chlorine termination present on the surface of the first layer 304 acts as a factor inhibiting an adsorption of silicon atom contained in the second gas to the surface of the first layer 304, that is, acts as an inhibitor.

After the second layer 306 is formed, the valve 243b is closed to stop the supply of the second gas into the process chamber 201. Then, a substance such as a gas phase substance remaining in the process chamber 201 is removed from the process chamber 201 by substantially the same process procedure and the same process conditions as the purge step of the step (a2) (purge step).

As the second gas, for example, the silane-based gas containing silicon (which is a primary (main) element constituting the film formed on the wafer 200) may be used. As the silane-based gas, for example, a gas containing silicon and free of halogen may be used, As the silane-based gas, for example, a gas such as monosilane (SiH₄) gas and disilane (Si₂H₆) gas may be used. As the second gas, for example, one or more of the gases exemplified above as the silane-based gas may be used.

<Step (A): Performing First Cycle First Predetermined Number of Times (Film-forming Step)>

In the step (A), by performing the first cycle wherein the step (a) and the step (b) described above are performed non-simultaneously (that is, in a non-synchronized manner) in this order the first predetermined number of times (m times, wherein m is an integer equal to or greater than 1), it is possible to form the film 308 on the wafer 200. For example, a silicon film formed by laminating the second layer 306 is formed as the film 308 on the wafer 200. Further, in FIG. 4, “1^{st} CYCLE”, “2^{nd} CYCLE” and “m^{th} CYCLE” related to the step (a) and the step (b) indicate “a first execution of the first cycle”, “a second execution of the first cycle” and “an m^{th} execution of the first cycle”, respectively. As described above, for example, since the first layer 304 acts as the inhibitor and the density of the first layer 304 in the vicinity of the opening of the inner surface of the concave structure 300 is higher than the density of the first layer 304 in the vicinity of the bottom of the inner surface of the concave structure 300, the film 308 can grow bottom-up from the bottom toward the opening of the inner surface of the concave structure 300 so as to fill the concave structure 300 with the film 308 (see FIG. 5D). Thereby, it is possible to form the film 308 which is void-free and seamless in the concave structure 300, and it is possible to improve filling characteristics.

In step (b) described above, for example, at least part of chlorine atoms (halogen atoms) at chlorine terminations present on the surface of the first layer 304 may be desorbed from the surface of the first layer 304. As a result, an inhibitor effect of the first layer 304 may be insufficient and a bottom-up growth of the film 308 may be inhibited. However, by setting the first predetermined number of times twice or more, that is, by performing the first cycle described above twice or more, the first layer 304 whose surface is chlorine-terminated can be formed again. As a result, it is possible to maintain the inhibitor effect of the first layer 304, and it is also possible to continue the bottom-up growth of the film 308. Thereby, it is possible to form the film 308 which is void-free and seamless in the concave structure 300, and it is possible to improve the filling characteristics. Further, even when the chlorine atom (halogen atom) is desorbed from the surface of the first layer 304 in the step (b), the silicon atom (atom of the predetermined element) constituting the first layer 304 and was bonded to the chlorine atom desorbed from the surface of the first layer 304 may be regarded as the silicon atom (atom of the predetermined element) constituting the film 308 as it is.

By performing the step (b) described above, for example, under conditions where the second gas undergoes a vapor phase decomposition (or a thermal decomposition), silicon contained in the second gas is deposited on the wafer 200 in a multiple manner. Thereby, it is possible to improve a forming speed of the film 308.

<After-purge Step and Returning to Atmospheric Pressure Step>

After the step (A) is completed, the inert gas serving as the purge gas is supplied into the process chamber 201 through each of the nozzles 249a and 249b, and then is exhausted through the exhaust port 231a. Thereby, the inner atmosphere of the process chamber 201 is purged with the purge gas. As a result, a substance such as a residual gas and reaction by-products remaining in the process chamber 201 is removed from the process chamber 201 (after-purge step). Thereafter, the inner atmosphere of the process chamber 201 is replaced with the inert gas (substitution by inert gas), and the inner pressure of the process chamber 201 is returned to the normal pressure (atmospheric pressure) (returning to atmospheric pressure step).

<Boat Unloading Step and Wafer Discharging Step>

Thereafter, the seal cap 219 is lowered by the boat elevator 115 and the lower end of the manifold 209 is opened. Then, the boat 217 with the processed wafers 200 supported therein is unloaded (transferred) out of the reaction tube 203 through the lower end of the manifold 209 (boat unloading step). After the boat 217 is unloaded, the shutter 219s is moved such that the lower end opening of the manifold 209 is sealed by the shutter 219s through the O-ring 220c (shutter closing step). The processed wafers 200 are discharged (transferred) from the boat 217 after the boat 217 is unloaded out of the reaction tube 203 (wafer discharging step).

(3) Effects According to Present Embodiments

According to the present embodiments, it is possible to obtain one or more of the following effects.

(a) Since the chlorine termination present on the surface of the first layer 304 acts as the inhibitor inhibiting a formation of the second layer 306, for example, in a case where the concave structure 300 is formed on the surface of the wafer 200, by adjusting a density distribution of the first layer 304 in the concave structure 300, it is possible to control (adjust) a thickness distribution of the second layer 306. As a result, it is possible to form the film 308 with a desired thickness distribution within the concave structure 300.

Since the first gas contains silicon the same as the second gas, it is possible to improve the forming speed of the film 308 as compared with a case where the first gas does not contain silicon.

(b) In the step (a), since the density of the first layer 304 in the vicinity of the opening of the inner surface of the concave structure 300 is higher than the density of the first layer 304 in the vicinity of the bottom of the inner surface of the concave structure 300, the film 308 can grow bottom-up from the bottom toward the opening of the inner surface of the concave structure 300 so as to fill the concave structure 300 with the film 308. As a result, it is possible to form the film 308 which is void-free and seamless in the concave structure 300, and it is also possible to improve the filling characteristics.

(c) By using a gas free of hydrogen (H) as the first gas, it is possible to suppress a formation of a layer whose surface hydrogen-terminated on the wafer 200. For example, a hydrogen atom at a hydrogen termination may be more easily desorbed from the layer whose surface hydrogen-terminated as compared with a case where the chlorine atom at the chlorine termination atom is desorbed from a layer such as the first layer 304, when the layer whose surface hydrogen-terminated is formed on the wafer 200, it may be difficult to exhibit the inhibitor effect of the first layer 304. By using the gas free of hydrogen as the first gas, since the formation of the layer whose surface hydrogen-terminated can be suppressed, it is possible to sufficiently exhibit the inhibitor effect of the first layer 304.

(d) By using a gas free of a bond between silicon atoms (silicon-silicon bond) in one molecule of the gas as the first gas, it is possible to suppress a thermal decomposition of the first gas in the step (a1). When the first gas is thermally decomposed, in the step (a1), silicon contained in the first gas and adsorbed to the wafer 200 may easily contain a dangling bond. In the step (b), silicon contained in the second gas may bond to the dangling bond, and as a result, it may be difficult to exhibit the inhibitor effect of the first layer 304. By using the gas free of the bond between the silicon atoms in one molecule as the first gas, it is possible to sufficiently exhibit the inhibitor effect of the first layer 304.

(e) After the step (a), at least until the step (b) is started, by not supplying a gas different from each of the first gas and the second gas (wherein each of the first gas and the second gas reacts with the chlorine termination) to the wafer 200, it is possible to suppress a desorption of the chlorine atom at the chlorine termination present on the surface of the first layer 304. As a result, since the chlorine termination remains on the surface of the first layer 304, it is possible to exhibit the inhibitor effect in the step (b).

(4) Modified Examples

The process sequence of the substrate processing according to the embodiments described above may be modified as shown in the following modified examples. The modified examples may be appropriately combined. In addition, unless otherwise described, a process procedure and process conditions of each step of each of the modified examples or combinations thereof may be substantially the same as the process procedure and the process conditions of each step of the embodiments described above.

### First Modified Example

As in a process sequence shown below, after the film-forming step (that is, the step (A)) is performed, a step of supplying an etching gas capable of etching the film 308 to the wafer 200 (that s, a step (B)) may be performed, and then the step (A) may be performed. Both of p and q shown below are integers equal to or greater than 1.

[(first gas→purge)×n→second gas→purge]×m→etching gas→[(first gas→purge)×p→second gas→purge]×q

<Step (B)>

In the step (B), the etching gas capable of etching the film 308 is supplied to the wafer 200 in the process chamber 201 so as to etch (remove) a part of the film 308.

Specifically, the valve 243c is opened such that the etching gas is supplied into the gas supply pipe 232c. A flow rate of the etching gas supplied into the gas supply pipe 232c is adjusted by the MFC 241c. Then, the etching gas whose flow rate is adjusted is supplied into the process chamber 201 through the nozzle 249a, and is exhausted through the exhaust port 231a. Thereby, the etching gas is supplied to the wafer 200. Thus, the step (B) may also be referred to as an “etching gas supply step”. In the present step, simultaneously with a supply of the etching gas, the valves 243d and 243e may be opened such that the inert gas is supplied into the process chamber 201 through each of the nozzles 249a and 249b.

For example, the process conditions of the present step are as follows:
A process temperature: from 200° C. to 800° C., preferably from 300° C. to 600° C.;
A process pressure: from 10 kPa to 100 kPa, preferably from 20 kPa to 50 kPa;
A supply flow rate of the etching gas: from 0.01 slm to 10 slm, preferably from 0.1 slm to 5 slm; and
A supply time (time duration) of the etching gas: from 1 minute to 60 minutes, preferably from 10 minutes to 30 minutes.

The other process conditions of the present step are set to be substantially the same as those of the step (a1).

As the etching gas, for example, a halogen-containing gas such as chlorine (Cl₂) gas, fluorine (F₂) gas, chlorine trifluoride (ClF₃) gas, hydrogen chloride (HCl) gas and hydrogen fluoride (HF) gas may be used. As the etching gas, for example, one or more of the gases exemplified above as the halogen-containing gas may be used.

Even in the present modified example, it is possible to obtain substantially the same effects as in the embodiments described above.

By repeatedly performing the first cycle including the step (a) and the step (b), the opening of the inner surface of the concave structure 300 may be closed by the film 308 before an inside of the concave structure 300 is completely filled with the film 308. That is, a so-called “overhang state” may occur. In such a case, a void or a seam extending in a depth direction of the concave structure 300 may occur in the concave structure 300. According to the present modified example, by supplying the etching gas to the wafer 200 in accordance with the process conditions described above, it is possible to preferentially (or selectively) remove a part of the film 308 formed in the vicinity of the opening of the concave structure 300. As a result, for example, by eliminating the overhang state before the void or the seam is formed in the film 308 filled in the concave structure 300, it is possible to continuously perform the first cycle including the step (a) and the step (b). In addition, for example, even when the void or the seam is formed in the film 308 filled in the concave structure 300, it is possible to eliminate the void or the seam. After the void or the seam formed in the film 308 is eliminated, by further performing the step (A), it is possible to reliably form the film 308 which is void-free and seamless in the concave structure 300, and it is also possible to further improve the filling characteristics.

Further, after the step (A) is performed, a third cycle including the step (B) and the step (A) may be performed a plurality number of times. In the third cycle, the step (A) is performed after the step (B). As a result, it is possible to more reliably form the film 308 which is void-free and seamless in the concave structure 300, and it is also possible to more further improve the filling characteristics.

### Second Modified Example

In the step (A), the second predetermined number of times in the second cycle of the first cycle including the step (a) and the step (b) in a case of forming the film 308 in the vicinity of the opening of the inner surface of the concave structure 300 may be set to be smaller than the second predetermined number of times in the second cycle of the first cycle including the step (a) and the step (b) in a case of forming the film 308 in the vicinity of the bottom of the inner surface of the concave structure 300. As the film-forming process (filling process) progresses in the concave structure 300, an aspect ratio of the concave structure 300 (that is, a ratio of a depth of the concave structure 300 to a width of the concave structure 300) gradually decreases. Therefore, it is possible to easily form the first layer 304 with a high density from the bottom toward the opening of the inner surface of the concave structure 300. As a result, a forming speed of the second layer 306 may be lowered throughout the concave structure 300, and a productivity of the filling process may be lowered. Further, when the filling process is performed in a state where the first layer 304 with the high density is formed from the bottom to the opening of the inner surface of the concave structure 300, a thickness of the film 308 in the vicinity of the opening may be greater than the thickness of the film 308 in the vicinity of the bottom of the inner surface of the concave structure 300. In such a case, the void or the seam may occur in the concave structure 300. As a result, the productivity of the filling process may be lowered. However, according to the present modified example, by setting the second predetermined number of times in the second cycle of the first cycle in the case of forming the film 308 in the vicinity of the opening of the inner surface of the concave structure 300 (for example, at a middle stage or a final stage of the filling process, that is, during a predetermined number of executions of the first cycle at a middle stage or a final stage of the step (A)) to be smaller than the second predetermined number of times in the second cycle of the first cycle in the case of forming the film 308 in the vicinity of the bottom of the inner surface of the concave structure 300 (for example, at an initial stage of the filling process, that is, during a predetermined number of executions of the first cycle at an initial stage of the step (A)), it is possible to form the first layer 304 with a desired density distribution on the inner surface of the concave structure 300. Thereby, it is possible to improve the filling characteristics. Further, for example, by reducing the supply flow rate of the first gas per cycle (that is, the second cycle) in the step (a) or by shortening the supply time of the first gas per cycle (that is, the second cycle) in the step (a) as the filling process progresses, it is possible to obtain substantially the same effects of the present modified example.

### Other Embodiments of Present Disclosure

While the technique of the present disclosure is described in detail by way of the embodiments and the modified examples described above, the technique of the present disclosure is not limited thereto. The technique of the present disclosure may be modified in various ways without departing from the scope thereof.

For example, the embodiments and the modified examples described above are described by way of an example in which the film 308 is gradually formed from the bottom toward the opening of the inner surface of the concave structure 300 (that is, the bottom-up growth of the film 308 is performed). However, the technique of the present disclosure is not limited thereto. For example, the film 308 may be conformally formed to the inner surface of the concave structure 300. Even in such a case, it is possible to obtain substantially the same effects as in the embodiments or the modified examples described above.

For example, the embodiments and the modified examples described above are described by way of an example in which, in the step (a), the density of the first layer 304 in the vicinity of the opening of the inner surface of the concave structure 300 is set to be higher than the density of the first layer 304 in the vicinity of the bottom of the inner surface of the concave structure 300. However, the technique of the present disclosure is not limited thereto. For example, the density (coarseness) distribution of the first layer 304 in the concave structure 300 may be adjusted in any other desired manner. Even in such a case, it is possible to obtain substantially the same effects as in the embodiments or the modified examples described above. In particular, it is possible to remarkably obtain substantially the same effects in a case where the bottom-up growth of the film 308 is performed or in a case where the film 308 is conformally formed.

Although not specifically described in the embodiments described above, the larger the aspect ratio of the concave structure 300, the more easily the overhang state occurs. As a result, the void and the seam may easily occur in the concave structure 300. According to the technique of the present disclosure, when the aspect ratio of the concave structure 300 is large, specifically in a case where the aspect ratio of the concave structure 300 is equal to or greater than 10, it is possible to remarkably obtain an effect of improving the filling characteristics.

For example, the embodiments and the modified examples described above are described by way of an example in which the surface of the first layer 304 is chlorine-terminated. However, the technique of the present disclosure is not limited thereto. For example, the surface of the first layer 304 may be fluorine-terminated, bromine-terminated or iodine-terminated. Even in such a case, it is possible to obtain substantially the same effects as in the embodiments or the modified examples described above.

For example, the embodiments and the modified examples described above are described by way of an example in which the silane-based gas containing silicon as the predetermined element is used as the first gas. However, the technique of the present disclosure is not limited thereto. For example, as the first gas, a gas containing a metalloid element such as boron (B), germanium (Ge) and arsenic (As) as the predetermined element may be used. Further, as the first gas, a gas containing a metal element such as the predetermined element may be used. For example, as the first gas, a gas such as titanium tetrachloride (TiCl₄) gas containing titanium (Ti), zirconium tetrachloride (ZrCl₄) gas containing zirconium (Zr) and hafnium tetrachloride (HfCl₄) containing hafnium (Hf) may be used. Even in such a case, it is possible to obtain substantially the same effects as in the embodiments or the modified examples described above.

It is preferable that recipes used in processes are prepared individually in accordance with contents of the processes and are written and stored in the memory 121c via an electric communication line or the external memory 123. When starting each process, it is preferable that the CPU 121a selects an appropriate recipe among the recipes stored in the memory 121c in accordance with the contents of each process. Thus, various films of different composition ratios, qualities and thicknesses can be formed in a reproducible manner and in a universal manner by using a single substrate processing apparatus (that is, the substrate processing apparatus). In addition, since a burden on an operating personnel of the substrate processing apparatus can be reduced, various processes can be performed quickly while avoiding a malfunction of the substrate processing apparatus.

The recipe described above is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via the electric communication line or the recording medium in which the new recipe is stored. Further, the existing recipe already stored in the substrate processing apparatus may be directly changed to the new recipe by operating the input/output device 122 of the substrate processing apparatus.

For example, the embodiments and the modified examples described above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of simultaneously processing one or several substrates is used to form the film. For example, the embodiments and the modified examples described above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedure and the process conditions of each process using the substrate processing apparatuses exemplified above may be substantially the same as those of the embodiments or the modified examples described above. Even in such a case, it is possible to obtain substantially the same effects as in the embodiments or the modified examples described above.

Further, the embodiments and the modified examples described above may be appropriately combined. The process procedure and the process conditions of each combination thereof may be substantially the same as those of the embodiments or the modified examples described above.

According to some embodiments of the present disclosure, it is possible to the technique capable of forming the film with the desired thickness distribution, for example, in the concave structure of the substrate.

What is claimed is:

1. A substrate processing method comprising
(A) forming a film containing a predetermined element on a substrate by performing a first cycle a first predetermined number of times,
wherein the first cycle comprises:
(a) forming a first layer containing the predetermined element by performing a second cycle a second predetermined number of times, wherein a surface of the first layer is halogen-terminated and wherein the second cycle comprises:
(a1) supplying a first gas containing the predetermined element and a halogen element to the substrate; and
(a2) removing the first gas from a space in which the substrate is accommodated; and
(b) forming a second layer containing the predetermined element by supplying a second gas containing the predetermined element to the substrate on which the first layer is formed.

2. The substrate processing method of claim 1, wherein, in (b), a halogen termination terminating the surface of the first layer inhibits an atom of the predetermined element contained in the second gas from being adsorbed to the surface of the first layer.

3. The substrate processing method of claim 1, wherein the first predetermined number of times is set to be twice or more.

4. The substrate processing method of claim 3, wherein a concave structure is provided on a surface of the substrate, and
wherein the first predetermined number of times is equal to the number of times that the concave structure is filled with the film in (A).

5. The substrate processing method of claim 3, wherein, in (b), at least part of halogen atoms at halogen terminations terminating the surface of the first layer is desorbed from the surface of the first layer.

6. The substrate processing method of claim 1, wherein, after (a) and at least until (b) is started, a gas reactive with a halogen termination terminating the surface of the first layer and different from each of the first gas and the second gas is not supplied to the substrate.

7. The substrate processing method of claim 1, wherein the first gas comprises a gas free of hydrogen.

8. The substrate processing method of claim 1, wherein the first gas comprises a gas free of a bond between atoms of the predetermined element in one molecule of the gas.

9. The substrate processing method of claim 1, wherein a concave structure is provided on a surface of the substrate, and
wherein, in (a), a density of the first layer is set to be higher at a portion of an inner surface of the concave structure than at other portion of the inner surface of the concave structure.

10. The substrate processing method of claim 9, wherein, in (a), the density of the first layer is set to be higher in vicinity of an opening of the inner surface of the concave structure than in vicinity of a bottom of the inner surface of the concave structure.

11. The substrate processing method of claim 1, wherein the second predetermined number of times is set to be twice or more.

12. The substrate processing method of claim 10, wherein, in (A), the second predetermined number of times in the second cycle of (a) in the first cycle of (A) when forming the film in vicinity of the opening of the inner surface of the concave structure is set to be smaller than the second predetermined number of times in the second cycle of (a) in the first cycle of (A) when forming the film in vicinity of the bottom of the inner surface of the concave structure.

13. The substrate processing method of claim 9, wherein an execution time of (a1) is set such that a ratio of the density of the first layer formed in vicinity of a bottom of the inner surface of the concave structure to the density of the first layer formed in vicinity of an opening of the inner surface of the concave structure is set to be a desired ratio.

14. The substrate processing method of claim 9, wherein a supply flow rate of the first gas in (a1) is set such that a ratio of the density of the first layer formed in vicinity of a bottom of the inner surface of the concave structure to the density of the first layer formed in vicinity of an opening of the inner surface of the concave structure is set to be a desired ratio.

15. The substrate processing method of claim 1, wherein (b) is performed under conditions in which the second gas undergoes a vapor phase decomposition.

16. The substrate processing method of claim 1, further comprising:
(B) removing a part of the film by supplying an etching gas to the substrate on which the film is formed.

17. The substrate processing method of claim 16, wherein (A) is further performed after (B), and
wherein a third cycle comprising (A) and (B) is performed a plurality number of times.

18. A method of manufacturing a semiconductor device, comprising the substrate processing method of claim 1.

19. A non-transitory computer-readable recording medium storing a program that causes a substrate processing apparatus, by a computer, to perform:
(A) forming a film containing a predetermined element on a substrate by performing a first cycle a first predetermined number of times,
wherein the first cycle comprises:
(a) forming a first layer containing the predetermined element by performing a second cycle a second predetermined number of times, wherein a surface of the first layer is halogen-terminated and wherein the second cycle comprises:
(a1) supplying a first gas containing the predetermined element and a halogen element to the substrate; and
(a2) removing the first gas from a space in which the substrate is accommodated; and
(b) forming a second layer containing the predetermined element by supplying a second gas containing the predetermined element to the substrate on which the first layer is formed.

20. A substrate processing apparatus comprising:
a first gas supplier configured to supply a first gas containing a predetermined element and a halogen element to a substrate;
an exhauster configured to remove the first gas from a space in which the substrate is accommodated;
a second gas supplier configured to supply a second gas containing the predetermined element to the substrate; and
a controller configured to be capable of controlling the first gas supplier, the exhauster and the second gas supplier so as to perform:
(A) forming a film containing the predetermined element on the substrate by performing a first cycle a first predetermined number of times,
wherein the first cycle comprises:
(a) forming a first layer containing the predetermined element by performing a second cycle a second predetermined number of times, wherein a surface of the first layer is halogen-terminated and wherein the second cycle comprises:
(a1) supplying the first gas to the substrate; and
(a2) removing the first gas from the space in which the substrate is accommodated; and
(b) forming a second layer containing the predetermined element by supplying the second gas to the substrate on which the first layer is formed.
